(19) United States
(12) Patent Application Publication
(10) Pub. No.: US 2024/0274762 A1
(43) Pub. Date: Aug. 15, 2024

(54) LED PACKAGE

(71) Applicant: Samsung Electronics Co., Ltd, Suwon-si (KR)

(72) Inventors: Jihoon YUN, Suwon-si (KR); Daesup Kim, Suwon-si (KR); Sungmok Hong, Suwon-si (KR); Jungsung Kim, Suwon-si (KR); Mihwa Yu, Suwon-si (KR)

(21) Appl. No.: 18/433,643

(22) Filed: Feb. 6, 2024

(30) Foreign Application Priority Data
Feb. 14, 2023 (KR) 10-2023-0019547

(51) Int. Cl. H01L 33/54; H01L 33/48

(52) U.S. Cl. CPC H01L 33/54; H01L 33/483

(57) ABSTRACT

A light emitting diode (LED) package includes a body including a body molding layer having an opening, and a metal plate surrounded by the body molding layer, an upper surface of the metal plate being exposed through the opening of the body molding layer; an LED chip on the upper surface of the metal plate exposed through the opening of the body molding layer; and a lens molding layer, the lens molding layer including a lens portion on the LED chip and a peripheral portion on the body molding layer, wherein the body molding layer includes a plurality of recess regions adjacent to the opening of the body molding layer and extending outwardly in a radial direction of the opening of the body molding layer, and the peripheral portion fills the plurality of recess regions.

### CROSS-REFERENCE TO RELATED APPLICATION

This application is based on and claims priority under 35 U.S.C. § 119 to Korean Patent Application No. 10-2023-0019547, filed on Feb. 14, 2023, in the Korean Intellectual Property Office, the disclosure of which is incorporated by reference herein in its entirety.

### BACKGROUND

### 1. Field

Embodiments relate to a light emitting diode (LED) package.

### 2. Description of the Related Art

LED chips and LED packages including the LED chips have various advantages, such as low power consumption, high brightness, and long lifespan, and thus, their application areas as light sources may be gradually expanding. Each of the LED packages may include a lens molding layer having a dome shape so as to emit light generated by the LED chips to the outside.

### SUMMARY

The embodiments may be realized by providing a light emitting diode (LED) package including a body including a body molding layer having an opening, and a metal plate surrounded by the body molding layer, an upper surface of the metal plate being exposed through the opening of the body molding layer; an LED chip on the upper surface of the metal plate exposed through the opening of the body molding layer; and a lens molding layer, the lens molding layer including a lens portion on the LED chip and a peripheral portion on the body molding layer, wherein the body molding layer includes a plurality of recess regions adjacent to the opening of the body molding layer and extending outwardly in a radial direction of the opening of the body molding layer, and the peripheral portion fills the plurality of recess regions.

The embodiments may be realized by providing a light emitting diode (LED) package including a body including a body molding layer having an opening, and a metal plate surrounded by the body molding layer, an upper surface of the metal plate being exposed through the opening of the body molding layer; an LED chip on the upper surface of the metal plate exposed through the opening of the body molding layer; and a lens molding layer including a lens portion on the LED chip and a peripheral portion on the body molding layer, wherein the body molding layer includes a recess region extending in a circumferential direction around the opening of the body molding layer, and the peripheral portion fills the recess region.

The embodiments may be realized by providing a light emitting diode (LED) package including a body including a body molding layer having an opening, and a metal plate surrounded by the body molding layer, an upper surface of the metal plate being exposed through the opening of the body molding layer; an LED chip on the upper surface of the metal plate exposed through the opening of the body molding layer; an encapsulation layer filling the opening of the body molding layer and covering sidewalls of the LED chip; and a lens molding layer including a lens portion on the LED chip and the encapsulation layer, and a peripheral portion on a portion of the body molding layer located outside the opening of the body molding layer, wherein the body molding layer includes a plurality of recess regions adjacent to the opening of the body molding layer and extending outwardly in a radial direction of the opening of the body molding layer, and the peripheral portion fills the plurality of recess regions.

### BRIEF DESCRIPTION OF THE DRAWINGS

Features will be apparent to those of skill in the art by describing in detail exemplary embodiments with reference to the attached drawings in which:

FIG. 1 is a perspective view showing a light emitting diode (LED) package according to an embodiment;

FIG. 2 is a perspective view showing a partial configuration of an LED package according to an embodiment;

FIG. 3 is a cross-sectional view taken along line A-A′ of FIG. 1;

FIG. 4 is a cross-sectional view taken along line B-B′ of FIG. 1;

FIG. 5 is a perspective view showing an LED package according to an embodiment;

FIG. 6 is a perspective view showing an LED package according to an embodiment;

FIG. 7 is a perspective view showing an LED package according to an embodiment;

FIG. 8 is a perspective view showing a partial configuration of an LED package according to an embodiment; and

FIG. 9 is a cross-sectional view taken along line C-C′ of FIG. 7.

### DETAILED DESCRIPTION

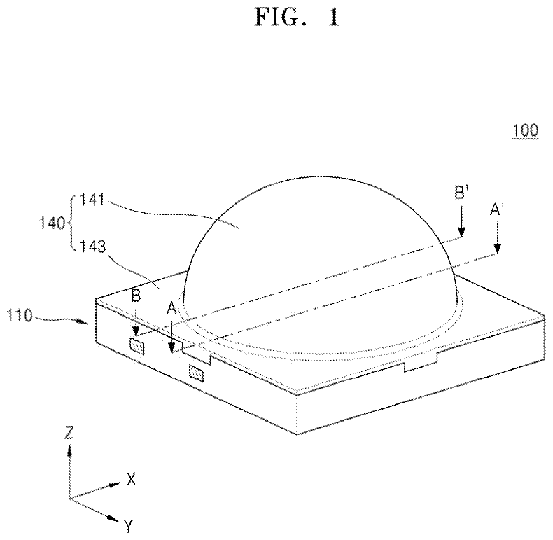

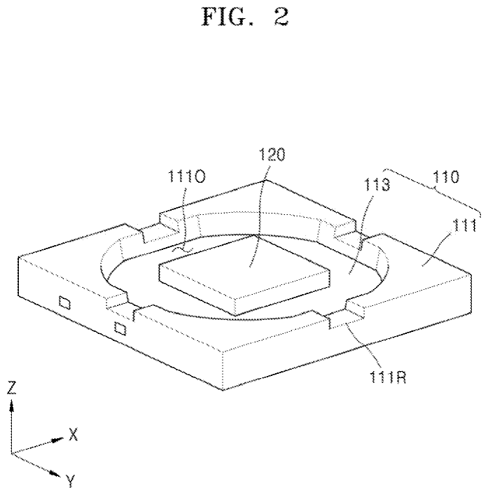

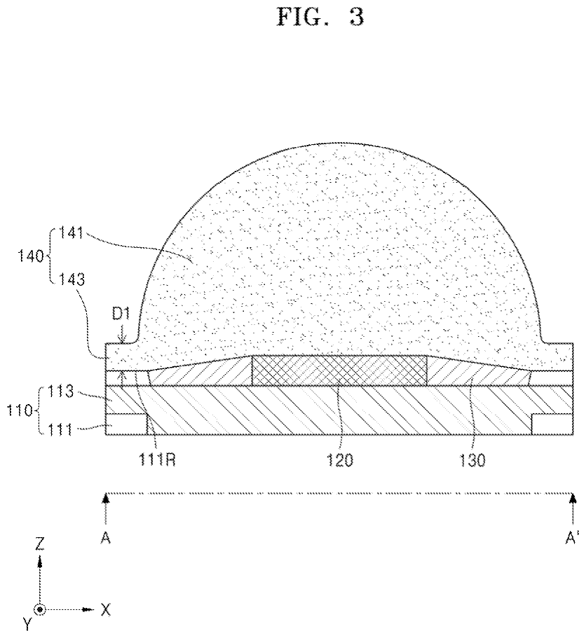

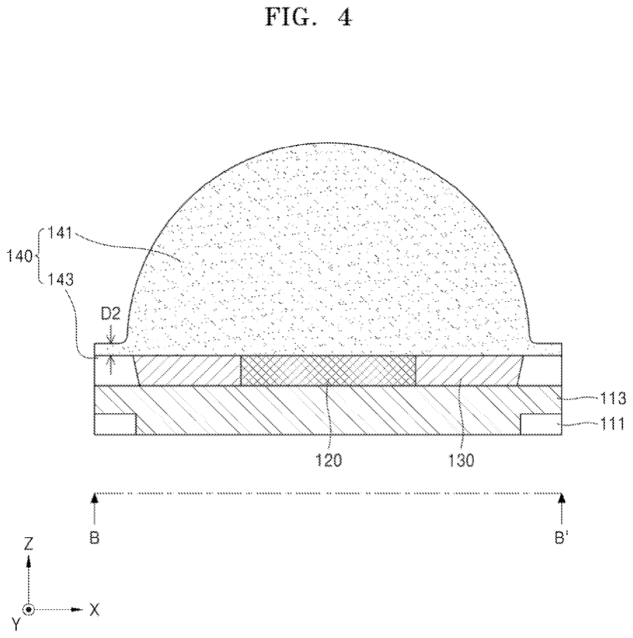

FIG. 1 is a perspective view showing an LED package 100 according to an embodiment. FIG. 2 is a perspective view showing a partial configuration of the LED package 100 according to an embodiment. FIG. 3 is a cross-sectional view taken along line A-A′ of FIG. 1. FIG. 4 is a cross-sectional view taken along line B-B′ of FIG. 1. Specifically, FIG. 2 is a perspective view showing a partial configuration of the LED package 100 from which an encapsulation layer 130 and a lens molding layer 140 are omitted.

Referring to FIGS. 1 to 4, the LED package 100 may include a body 110, an LED chip 120, the encapsulation layer 130, and the lens molding layer 140.

The body 110 may be a frame for mounting and supporting the LED chip 120. The body 110 may include a body molding layer 111 and a metal plate 113.

Unless specifically defined below, two directions parallel to a lower surface of the body 110 and perpendicular to each other are respectively defined as a first horizontal direction (X direction) and a second horizontal direction (Y direction), and a direction perpendicular to the lower surface of the body 110 is defined as the vertical direction (Z direction).

The body molding layer 111 may have an opening 111O at a center of the body molding layer 111. The opening 111O may pass through at least a portion of the body molding layer 111 in the vertical direction, and the bottom of the opening 111O may expose a portion of the upper surface of the metal plate 113 of the body 110. The opening 111O may have a shape defined by both the upper surface of the metal plate 113 exposed via the opening 111O and an inner sidewall of the body molding layer 111 inclined at an inclination angle from the upper surface of the exposed metal plate 113. In an implementation, the inner sidewall of the body molding layer 111 may be inclined such that a horizontal width of the opening 111O increases with increasing distance from the upper surface of the metal plate 113 (e.g., in the Z direction).

In an implementation, the opening 111O may have a circular shape on a plane perpendicular to the vertical direction. In an implementation, the opening 111O may have a polygonal shape on a plane perpendicular to the vertical direction.

The body molding layer 111 may include a plurality of recess regions 111R adjacent to the opening 111O and above or overlying a portion of the metal plate 113 that is not exposed through the opening 111O. Each of the plurality of recess regions 111R may include a region in which at least a portion of the body molding layer 111 is recessed in the vertical direction (e.g., a thinner portion of the body molding layer 111). In an implementation, this region may include a region in which the upper surface of the metal plate 113 is not exposed. In an implementation, the upper surface of the body molding layer 111 in the plurality of recess regions 111R may be at a lower vertical level than the upper surface of the body molding layer 111 that is not recessed, and may be at a higher vertical level than the upper surface of the metal plate 113. In an implementation, each of the plurality of recess regions 111R may extend (e.g., outwardly) in the radial direction of the opening 111O. In an implementation, each of the plurality of recess regions 111R may have a quadrangular shape on a plane perpendicular to the vertical direction (e.g., in a plan view). In an implementation, each of the plurality of recess regions 111R may have a rectangular shape on a plane perpendicular to the vertical direction. In an implementation, each of the plurality of recess regions 111R may have a cross-section that is perpendicular to the horizontal direction and may have a quadrangular shape. In an implementation, some of the plurality of recess regions 111R may have a cross-section perpendicular to the first horizontal direction and having a quadrangular shape, and the other recess regions 111R may have a cross-section perpendicular to the second horizontal direction and having a quadrangular shape. In an implementation, the plurality of recess regions 111R may be spaced from a central point of the opening 111O by the same distance. In an implementation, the plurality of recess regions 111R may be spaced apart from the central point of the opening 111O by the same distance as the radius of the opening 111O. In an implementation, the plurality of recess regions 111R may be line-symmetric with each other with respect to a virtual line that passes through the central point of the opening 111O. In an implementation, the recess regions 111R facing each other among the plurality of recess regions 111R may be line-symmetric with each other with respect to a virtual line passing through the central point of the opening 111O.

In an implementation, the body molding layer 111 may include a resin. The resin may include, e.g., a thermoplastic resin, such as polyphthalamide (PPA) and polycyclohexylenedimethylene terephthalate (PCT), a thermosetting resin, such as an epoxy molding compound (EMC), or a combination thereof. As used herein, the term “or” is not necessarily an exclusive term, e.g., “A or B” would include A, B, or A and B.

The metal plate 113 may be covered (e.g., partially covered) by the body molding layer 111. A portion of the upper surface of the metal plate 113 may be exposed through the bottom of the opening 111O of the body molding layer 111. In an implementation, the metal plate 113 may include a metal material. The metal material may include, e.g., copper or the like.

The LED chip 120 may be on the upper surface of the metal plate 113 exposed through the bottom of the opening 111O. In an implementation, the LED chip 120 may be mounted, in a flip-chip structure, on the exposed upper surface of the metal plate 113. In an implementation, solder and bumps may be further provided between the LED chip 120 and the metal plate 113. In an implementation, the LED chip 120 may be mounted, in an epi-up structure, on the exposed upper surface of the metal plate 113. In an implementation, the LED chip 120 may be electrically connected to the metal plate 113 by a bonding wire.

The LED chip 120 may include a first conductive semiconductor layer, an active layer, and a second conductive semiconductor layer. In an implementation, the first conductive semiconductor layer may include a single crystal nitride having a composition of, e.g., AlₓIn_{y}Ga_{1-x-y}N (in which 0≤x≤1, 0≤y≤1, and 0≤x+y≤1). The first conductive semiconductor layer may include a semiconductor doped with n-type impurities. In an implementation, the first conductive semiconductor layer may include GaN doped with Si or the like.

The active layer may be on the first conductive semiconductor layer. The active layer may emit light having certain energy due to recombination of electrons and holes. In an implementation, the active layer may have a multiple quantum well (MQW) structure in which quantum well layers and quantum barrier layers are alternately stacked. In an implementation, the thickness of each of the quantum well layers and the quantum barrier layers may be in a range of about 3 nm to about 10 nm. In an implementation, the MQW may include a multiple stack structure of InGaN and GaN. In an implementation, the active layer may have a single quantum well (SQW) structure.

The second conductive semiconductor layer may include a single crystal nitride doped with p-type impurities and having a composition of, e.g., AlₓIn_{y}Ga_{1-x-y}N (in which 0≤x≤1, 0≤y≤1, and 0≤x+y≤1). In an implementation, the p-type impurities may include, e.g., Mg.

The encapsulation layer 130 may fill the opening 111O. The encapsulation layer 130 may be in the opening 111O and between the LED chip 120 and the body molding layer 111 in the plurality of recess regions 111R and may cover sidewalls of the LED chip 120 and one sidewall of the body molding layer 111 in or at each of the plurality of recess regions 111R. In an implementation, the encapsulation layer 130 may have inclined upper surfaces in some regions adjacent to the plurality of recess regions 111R and may have upper surfaces parallel with the upper surface of the metal plate 113 in the other regions not adjacent to the plurality of recess regions 111R. In an implementation, the encapsulation layer 130 may have upper surfaces, which are inclined downwardly at a constant inclination angle with a distance from the LED chip 120 in some regions adjacent to the plurality of recess regions 111R and may have upper surfaces parallel with the upper surface of the metal plate 113 in the other regions not adjacent to the plurality of recess regions 111R. In an implementation, the upper surface of the encapsulation layer 130 may be at a higher vertical level than the upper surface of the body molding layer 111 in the plurality of recess regions 111R. In an implementation, the encapsulation layer 130 may include a material having high reflectivity. In an implementation, the encapsulation layer 130 may include TiO₂, silicon, or a combination thereof. In an implementation, the encapsulation layer 130 may be omitted. In an implementation, the lens molding layer 140 may fill the opening 111O instead of the encapsulation layer 130.

The lens molding layer 140 may be on the body 110, the LED chip 120, and the encapsulation layer 130. The lens molding layer 140 may cover the upper surface of the body 110, the upper surface of the LED chip 120, and the upper surface of the encapsulation layer 130. The lens molding layer 140 may include a light-transmitting material via which light generated by the LED chip 120 passes and discharges to the outside. The lens molding layer 140 may include, e.g., transparent silicon. In an implementation, the lens molding layer 140 may include a light dispersion material. The light dispersion material may include, e.g., TiO₂ or SiO₂.

The lens molding layer 140 may include a lens portion 141 and a peripheral portion 143. During a process of forming the lens molding layer 140, the lens portion 141 and the peripheral portion 143 may be formed simultaneously and integrally. The lens portion 141 may have a dome shape. The lens portion 141 may include a portion of the lens molding layer 140 that overlaps the opening 111O of the body molding layer 111 in the vertical direction. The lens portion 141 may pass or transmit light generated from the LED chip 120 and then discharge the same to the outside. During the process of forming the lens molding layer 140, the peripheral portion 143 may serve as a movement path for materials of the lens molding layer 140. The peripheral portion 143 may include a portion of the lens molding layer 140 that does not overlap the opening 111O of the body molding layer 111 in the vertical direction. In an implementation, the peripheral portion 143 may fill the plurality of recess regions 111R of the body molding layer 111. In an implementation, the lower surface of one portion of the peripheral portion 143 that fills the plurality of recess regions 111R may be at a lower vertical level than the lower surface of another portion of the peripheral portion 143 that does not fill the plurality of recess regions 111R. In an implementation, a portion of the peripheral portion 143 filling the plurality of recess regions 111R may have a first height D1 (e.g., height) in the vertical direction, and the other portion of the peripheral portion 143 (other than the portion filling the plurality of recess regions 111R) may have a second height D2 in the vertical direction. In an implementation, the first height D1 may be greater than the second height D2. The first height D1 may be about 1/10 to about ⅕ of the height of the lens portion 141 in the vertical direction. In an implementation, the upper surface of the portion of the peripheral portion 143 that fills the plurality of recess regions 111R may be at the same vertical level as the upper surface of the other portion of the peripheral portion 143 that does not fill the plurality of recess regions 111R. In an implementation, the upper surface of the peripheral portion 143 may be flat (e.g., parallel with an upper surface of the metal plate 113). In an implementation, a portion of the peripheral portion 143 filling the plurality of recess regions 111R may have the first height D1 in the vertical direction and may have a rectangular cross-section perpendicular to the second horizontal direction. In an implementation, the other portion of the peripheral portion 143 other than the portion filling the plurality of recess regions 111R may have the second height D2 in the vertical direction and may have a rectangular cross-section perpendicular to the second horizontal direction. In an implementation, the second height D2 may be less than or equal to ½ of the first height D1. In an implementation, the second height D2 may be about 1/10 to about ½ of the first height D1. As used herein, the terms “first,” “second,” and the like are merely for identification and differentiation, and are not intended to imply or require sequential inclusion (e.g., a third element and a fourth element may be described without implying or requiring the presence of a first element or second element).

The LED package 100 according to an embodiment may include the body 110, which includes the metal plate 113 and the body molding layer 111 having the plurality of recess regions 111R, and the lens molding layer 140, which includes the lens portion 141 and the peripheral portion 143. In an implementation, at least a portion of the peripheral portion 143 may fill the plurality of recess regions 111R of the body molding layer 111. In this case, a portion of the peripheral portion 143 that fills the plurality of recess regions 111R may have the first height D1 in the vertical direction, and the other portion of the peripheral portion 143 that does not fill the plurality of recess regions 111R may have the second height D2 in the vertical direction. In an implementation, the second height D2 may be less than the first height D1.

In a comparative LED package, in order to provide a path for materials of a lens molding layer included in the LED package, a peripheral portion may also be formed together with a lens portion during a process of forming the lens molding layer. However, part of light generated by a LED chip included in the comparative LED package may be emitted to the outside through the peripheral portion rather than the lens portion, which could deteriorate the light extraction efficiency thereof.

In the LED package 100 according to an embodiment, only a portion of the peripheral portion 143 that fills the plurality of recess regions 111R may have the first height D1 that is substantially the same as the peripheral portion of the comparative LED package in the vertical direction, and the other portion of the peripheral portion 143 that does not fill the plurality of recess regions 111R may have the second height D2 that is less than the first height D1 in the vertical direction. Accordingly, relatively little light generated by the LED chip 120 may be emitted through the peripheral portion 143 in the embodiment, compared to the comparative LED package. Accordingly, the light extraction efficiency of the LED package 100 according to an embodiment may be improved.

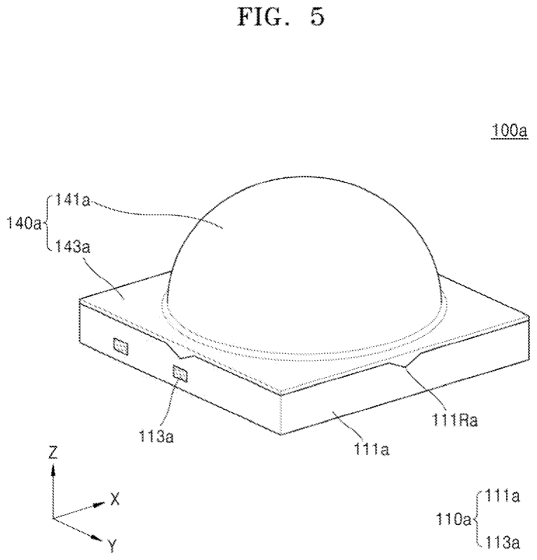

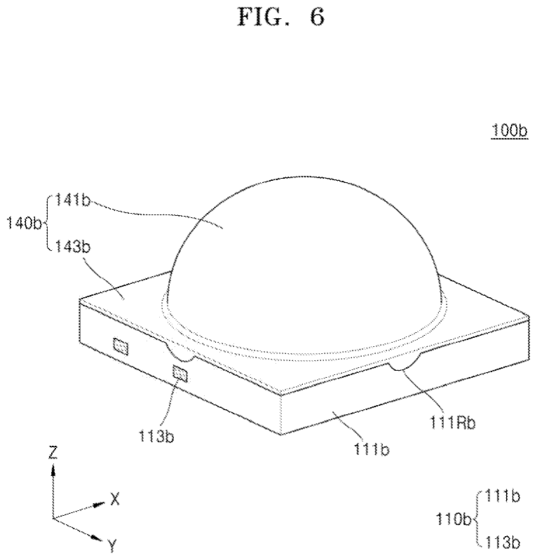

FIG. 5 is a perspective view showing an LED package 100a according to an embodiment. FIG. 6 is a perspective view showing an LED package 100b according to an embodiment. Each of components of the LED package 100a illustrated in FIG. 5 and each of components of the LED package 100b illustrated in FIG. 6 are similar to each of the components of the LED package 100 described with reference to FIGS. 1 to 4, and thus, the description focuses on differences therebetween.

Referring to FIG. 5, the LED package 100a may include a body 110a, an LED chip, an encapsulation layer, and a lens molding layer 140a.

The body 110a may include a body molding layer 111a and a metal plate 113a. The body molding layer 111a may have substantially the same opening as the opening 111O of the LED package 100 described with reference to FIGS. 1 to 4. The opening may expose at least a portion of an upper surface of the metal plate 113a. In an implementation, the body molding layer 111a may include a plurality of recess regions 111Ra adjacent to the opening and above or overlying a portion of the metal plate 113a that is not exposed through the opening. Each of the plurality of recess regions 111Ra may include a region in which at least a portion of the body molding layer 111a is recessed in the vertical direction, and this region may include a region in which the upper surface of the metal plate 113a is not exposed. In an implementation, each of the plurality of recess regions 111Ra may extend outwardly in the radial direction of the opening. In an implementation, each of the plurality of recess regions 111Ra may have a cross-section that is perpendicular to a horizontal direction and may have a triangular shape. In an implementation, some of the plurality of recess regions 111Ra may have a cross-section perpendicular to a first horizontal direction and may have a triangular shape, and the other recess regions 111Ra may have a cross-section perpendicular to a second horizontal direction and may have a triangular shape. In an implementation, the triangular shape may include, e.g., an equilateral triangle.

The LED chip and the encapsulation layer included in the LED package 100a may be on the body 110a in a manner substantially the same as or similar to the LED chip 120 and the encapsulation layer 130, respectively, described above with reference to FIGS. 1 to 4. Also, the LED chip and the encapsulation layer may have structures and materials substantially the same as or similar to the LED chip 120 and the encapsulation layer 130 of the LED package 100, respectively, described above with reference to FIGS. 1 to 4.

The lens molding layer 140a may be on the body 110a, the LED chip, and the encapsulation layer. The lens molding layer 140a may include a lens portion 141a and a peripheral portion 143a. The lens portion 141a may have a dome shape. The peripheral portion 143a may fill the plurality of recess regions 111Ra of the body molding layer 111a. In an implementation, a portion of the peripheral portion 143a filling the plurality of recess regions 111Ra may have a triangular cross-section in a direction perpendicular to the horizontal direction so as to correspond to or complement the cross-section of each of the plurality of recess regions 111Ra.

Referring to FIG. 6, the LED package 100b may include a body 110b, an LED chip, an encapsulation layer, and a lens molding layer 140b.

The body 110b may include a body molding layer 111b and a metal plate 113b. The body molding layer 111b may have substantially the same opening as the opening 111O of the LED package 100 described with reference to FIGS. 1 to 4. The opening may expose at least a portion of an upper surface of the metal plate 113b. In an implementation, the body molding layer 111b may include a plurality of recess regions 111Rb adjacent to the opening and above a portion of the metal plate 113b that is not exposed through the opening. Each of the plurality of recess regions 111Rb may include a region in which at least a portion of the body molding layer 111b is recessed in the vertical direction, and this region may include a region in which the upper surface of the metal plate 113b is not exposed. In an implementation, each of the plurality of recess regions 111Rb may extend outwardly in the radial direction of the opening. In an implementation, each of the plurality of recess regions 111Rb may have a cross-section that is perpendicular to a horizontal direction and may have a rounded or circular (e.g., semi-circular) shape. In an implementation, some of the plurality of recess regions 111Rb may have a cross-section perpendicular to a first horizontal direction and may have a circular shape, and the other recess regions 111Rb may have a cross-section perpendicular to a second horizontal direction and may have a circular shape. The rounded or circular shape may include, e.g., a circle (e.g., semi-circle) or an ellipse (e.g., a part of an ellipse).

The LED chip and the encapsulation layer included in the LED package 100b may be on the body 110b in a manner substantially the same as or similar to the LED chip 120 and the encapsulation layer 130, respectively, described above with reference to FIGS. 1 to 4. Also, the LED chip and the encapsulation layer may have structures and materials substantially the same as or similar to the LED chip 120 and the encapsulation layer 130 of the LED package 100, respectively, described above with reference to FIGS. 1 to 4.

The lens molding layer 140b may be on the body 110b, the LED chip, and the encapsulation layer. The lens molding layer 140b may include a lens portion 141b and a peripheral portion 143b. The lens portion 141b may have a dome shape. The peripheral portion 143b may fill the plurality of recess regions 111Rb of the body molding layer 111b. In an implementation, a portion of the peripheral portion 143b filling the plurality of recess regions 111Rb may have a circular cross-section in a direction perpendicular to the horizontal direction so as to correspond to or complement the cross-section of each of the plurality of recess regions 111Rb.

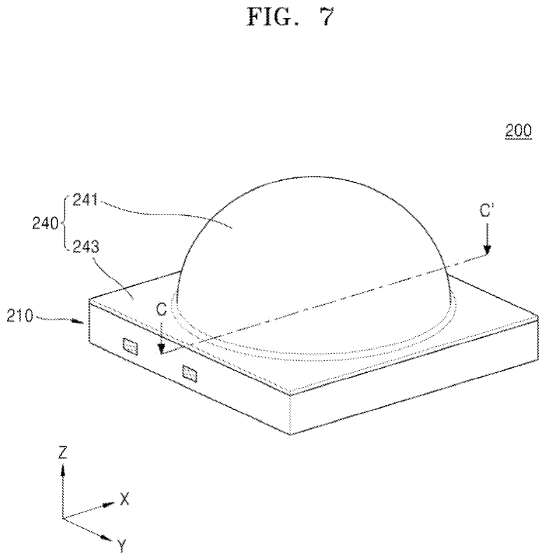

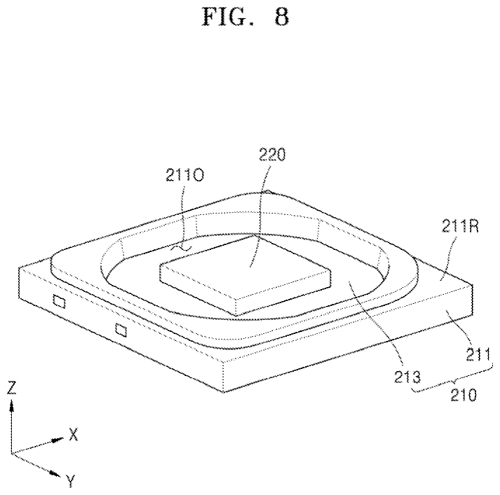

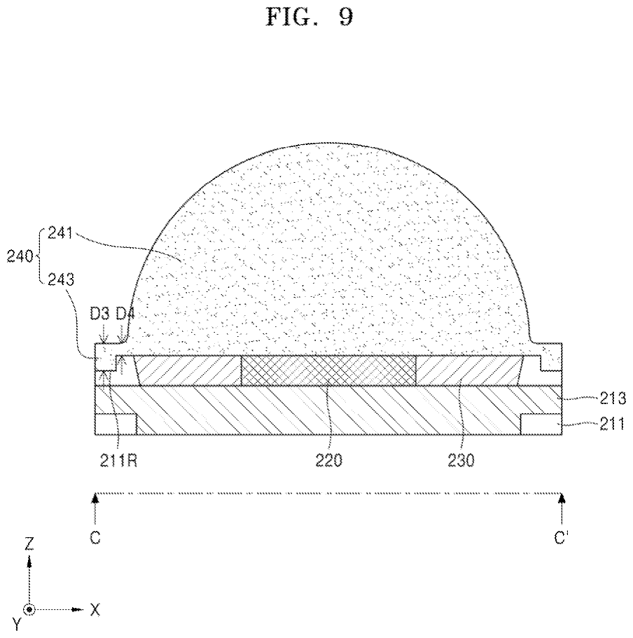

FIG. 7 is a perspective view showing an LED package 200 according to an embodiment. FIG. 8 is a perspective view showing a partial configuration of the LED package 200 according to an embodiment. FIG. 9 is a cross-sectional view taken along line C-C′ of FIG. 7. Specifically, FIG. 8 is a perspective view showing a partial configuration of the LED package 200 from which an encapsulation layer 230 and a lens molding layer 240 are omitted.

Referring to FIGS. 7 to 9, the LED package 200 may include a body 210, an LED chip 220, the encapsulation layer 230, and the lens molding layer 240.

The body 210 may be a frame for mounting and supporting the LED chip 220. The body 210 may include a body molding layer 211 and a metal plate 213.

The body molding layer 211 may have an opening 211O at the center of the body molding layer 211. The opening 211O may pass through at least a portion of the body molding layer 211 in the vertical direction, and the bottom of the opening 211O may expose a portion of the upper surface of the metal plate 213 inside the body 210.

In an implementation, the opening 211O may have a circular shape on a plane perpendicular to the vertical direction.

The body molding layer 211 may have a recess region 211R extending in the circumferential direction of the opening 211O and spaced apart from the opening 211O at the edge of the body molding layer 211 on a plane perpendicular to the vertical direction. The recess region 211R may include a region in which at least a portion of the body molding layer 211 is recessed in the vertical direction, and this region may include a region in which the upper surface of the metal plate 213 is not exposed. In an implementation, the recess region 211R may have a ring shape or a closed loop shape in a plan view. In an implementation, the recess region 211R may have a ring shape or closed loop shape that surrounds the opening 211O and a non-recessed region of the body molding layer 211 on a plane perpendicular to the vertical direction.

In an implementation, the body molding layer 211 may include a material that is substantially the same as or similar to that of the body molding layer 111 of the LED package 100 described with reference to FIGS. 1 to 4.

The metal plate 213 may have a structure that is substantially the same as or similar to that of the metal plate 113 of the LED package 100 described with reference to FIGS. 1 to 4. In an implementation, the metal plate 213 may include a material that is substantially the same as or similar to that of the metal plate 113 of the LED package 100 described with reference to FIGS. 1 to 4.

The LED chip 220 may be mounted on the upper surface of the metal plate 213 exposed through the bottom of the opening 211O. In an implementation, the LED chip 220 may include a structure that is substantially the same as or similar to that of the LED chip 120 of the LED package 100 described with reference to FIGS. 1 to 4.

The encapsulation layer 230 may fill the opening 211O. In an implementation, the upper surface of the encapsulation layer 230 may be at substantially the same vertical level as the upper surface of the LED chip 220. In an implementation, the upper surface of the encapsulation layer 230 may be at a higher vertical level than the upper surface of the body molding layer 211 in the recess region 211R. In an implementation, the encapsulation layer 230 may include a material that is substantially the same as or similar to that of the encapsulation layer 130 of the LED package 100 described with reference to FIGS. 1 to 4.

In an implementation, the encapsulation layer 230 may be omitted. In an implementation, the lens molding layer 240 may fill the opening 211O instead of the encapsulation layer 230.

The lens molding layer 240 may be on the body 210, the LED chip 220, and the encapsulation layer 230. The lens molding layer 240 may cover the upper surface of the body 210, the upper surface of the LED chip 220, and the upper surface of the encapsulation layer 230. The lens molding layer 240 may include, e.g., a material that is substantially the same as or similar to that of the lens molding layer 140 of the LED package 100 described with reference to FIGS. 1 to 4.

The lens molding layer 240 may include a lens portion 241 and a peripheral portion 243. During a process of forming the lens molding layer 240, the lens portion 241 and the peripheral portion 243 may be formed simultaneously and integrally. The lens portion 241 may have a dome shape. The lens portion 241 may include a portion of the lens molding layer 240 that overlaps the opening 211O of the body molding layer 211 in the vertical direction. The peripheral portion 243 may include a portion of the lens molding layer 240 that does not overlap the opening 211O of the body molding layer 211 in the vertical direction. In an implementation, the peripheral portion 243 may fill the recess region 211R of the body molding layer 211. In an implementation, the lower surface of a portion of the peripheral portion 243 that fills the recess region 211R may be at a lower vertical level than the lower surface of the other portion of the peripheral portion 243 that does not fill the recess region 211R. In an implementation, a portion of the peripheral portion 243 filling the recess region 211R may have a third height D3 in the vertical direction, and the other portion of the peripheral portion 243 other than the portion filling the plurality of recess region 211R may have a fourth height D4 in the vertical direction. Here, the third height D3 may be greater than the fourth height D4. The third height D3 may be about 1/10 to about ⅕ of the length or height of the lens portion 241 in the vertical direction. In an implementation, the upper surface of the portion of the peripheral portion 243 that fills the recess region 211R may be at the same vertical level as the upper surface of the other portion of the peripheral portion 243 that does not fill the recess region 211R. In an implementation, the upper surface of the peripheral portion 243 may be flat (e.g., parallel with an upper surface of the metal plate 213). In an implementation, the peripheral portion 243 may have a cross-section having an L-shape perpendicular to a second horizontal direction or a cross-section with a shape obtained by rotating the L-shape perpendicular to the second horizontal direction. In an implementation, a portion of the peripheral portion 243 may have the third height D3 that is relatively large in the vertical direction, and the other portion of the peripheral portion 243 may have the fourth height D4 that is relatively small in the vertical direction. In an implementation, the fourth height D4 may be less than or equal to ½ of the third height D3. In an implementation, the fourth height D4 may be about 1/10 to about ½ of the third height D3.

The LED package 200 according to an embodiment may include the body 210, which includes the metal plate 213 and the body molding layer 211 having the recess region 211R, and the lens molding layer 240, which includes the lens portion 241 and the peripheral portion 243. In an implementation, at least a portion of the peripheral portion 243 may fill the recess region 211R of the body molding layer 211. In an implementation, the portion of the peripheral portion 243 that fills the recess region 211R may have the third height D3 in the vertical direction, and the other portion of the peripheral portion 243 that does not fill the recess region 211R may have the fourth height D4 in the vertical direction. In an implementation, the fourth height D4 may be less than the third height D3.

In a comparative LED package, in order to provide a path for materials of a lens molding layer included in the LED package, a peripheral portion may also be formed together with a lens portion during a process of forming the lens molding layer. However, part of light generated by a LED chip included in the comparative LED package may be emitted to the outside through the peripheral portion rather than the lens portion, which could deteriorate the light extraction efficiency of the comparative LED package.

In the LED package 200 according to an embodiment, only a portion of the peripheral portion 243 that fills the recess region 211R may have the third height D3 substantially the same as the peripheral portion of the comparative LED package in the vertical direction, and the other portion of the peripheral portion 243 that does not fill the recess region 211R may have the fourth height D4 that is less than the third height D3 in the vertical direction. Accordingly, relatively little light generated by the LED chip 220 may be emitted through the peripheral portion 243 in the embodiment, compared to the comparative LED package. Accordingly, the light extraction efficiency of the LED package 200 according to an embodiment may be improved.

By way of summation and review, during a process of forming the lens molding layer, a peripheral portion, which may be connected to a lens portion having a dome shape and may have a flat upper surface, may be integrally formed with the lens portion. The peripheral portion may provide a path for materials of the lens molding layer during the process of forming the lens molding layer. Due to the presence of the peripheral portion, part of light generated by the LED chip may be emitted to the outside via the peripheral portion, which could deteriorate the light extraction efficiency of the LED package.

One or more embodiments may provide an LED package having a dome-shaped lens portion.

One or more embodiments may provide an LED package having good light extraction efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A light emitting diode (LED) package, comprising:
a body including a body molding layer having an opening, and a metal plate surrounded by the body molding layer, an upper surface of the metal plate being exposed through the opening of the body molding layer;
an LED chip on the upper surface of the metal plate exposed through the opening of the body molding layer; and
a lens molding layer, the lens molding layer including a lens portion on the LED chip and a peripheral portion on the body molding layer,
wherein:
the body molding layer includes a plurality of recess regions adjacent to the opening of the body molding layer and extending outwardly in a radial direction of the opening of the body molding layer, and
the peripheral portion fills the plurality of recess regions.

2. The LED package as claimed in claim 1, wherein the plurality of recess regions are spaced from a central point of the opening of the body molding layer by the same distance on a plane perpendicular to a vertical direction.

3. The LED package as claimed in claim 1, wherein each recess region of the plurality of recess regions has a quadrangular shape in a plan view.

4. The LED package as claimed in claim 1, wherein the plurality of recess regions are line-symmetric with each other.

5. The LED package as claimed in claim 1, wherein each recess region of the plurality of recess regions has a cross-section having a polygonal shape or a circular shape.

6. The LED package as claimed in claim 1, wherein:
one portion of the peripheral portion, which fills the plurality of recess regions, has a first height in a vertical direction,
another portion of the peripheral portion, which does not fill the plurality of recess regions, has a second height in the vertical direction, and
the second height is less than the first height.

7. The LED package as claimed in claim 6, wherein the second height is less than or equal to ½ of the first height.

8. The LED package as claimed in claim 6, wherein the first height is about 1/10 to about ⅕ of a height of the lens portion in the vertical direction.

9. The LED package as claimed in claim 1, wherein an upper surface of the peripheral portion is flat.

10. The LED package as claimed in claim 1, further comprising an encapsulation layer that fills the opening of the body molding layer.

11. The LED package as claimed in claim 10, wherein an upper surface of the encapsulation layer is at a higher vertical level than a lower surface of a portion of the peripheral portion which fills the plurality of recess regions.

12. A light emitting diode (LED) package, comprising:
a body including a body molding layer having an opening, and a metal plate surrounded by the body molding layer, an upper surface of the metal plate being exposed through the opening of the body molding layer;
an LED chip on the upper surface of the metal plate exposed through the opening of the body molding layer; and
a lens molding layer including a lens portion on the LED chip and a peripheral portion on the body molding layer,
wherein:
the body molding layer includes a recess region extending in a circumferential direction around the opening of the body molding layer, and
the peripheral portion fills the recess region.

13. The LED package as claimed in claim 12, wherein the recess region is spaced apart from the opening of the body molding layer on a plane perpendicular to a vertical direction.

14. The LED package as claimed in claim 12, wherein:
one portion of the peripheral portion, which fills the recess region, has a first height in a vertical direction,
another portion of the peripheral portion, which does not fill the recess region, has a second height in the vertical direction, and
the second height is less than the first height.

15. The LED package as claimed in claim 14, wherein the second height is less than or equal to ½ of the first height.

16. The LED package as claimed in claim 12, wherein an upper surface of the peripheral portion is flat.

17. The LED package as claimed in claim 12, further comprising an encapsulation layer that fills the opening of the body molding layer,
wherein an upper surface of the encapsulation layer is at a higher vertical level than a lower surface of a portion of the peripheral portion which fills the recess region.

18. A light emitting diode (LED) package, comprising:
a body including a body molding layer having an opening, and a metal plate surrounded by the body molding layer, an upper surface of the metal plate being exposed through the opening of the body molding layer;
an LED chip on the upper surface of the metal plate exposed through the opening of the body molding layer;
an encapsulation layer filling the opening of the body molding layer and covering sidewalls of the LED chip; and
a lens molding layer including a lens portion on the LED chip and the encapsulation layer, and a peripheral portion on a portion of the body molding layer located outside the opening of the body molding layer,
wherein:
the body molding layer includes a plurality of recess regions adjacent to the opening of the body molding layer and extending outwardly in a radial direction of the opening of the body molding layer, and
the peripheral portion fills the plurality of recess regions.

19. The LED package as claimed in claim 18, wherein:
one portion of the peripheral portion, which fills the plurality of recess regions, has a first height in a vertical direction,
another portion of the peripheral portion, which does not fill the recess regions, has a second height in the vertical direction, and
the second height is less than the first height.

20. The LED package as claimed in claim 19, wherein:
the first height is about 1/10 to about ⅕ of a height of the lens portion in the vertical direction, and
the second height is less than or equal to ½ of the first height.
